(19) United States
(12) Patent Application Publication
(10) Pub. No.: US 2013/0135915 A1
(43) Pub. Date: May 30, 2013

(54) SEMICONDUCTOR APPARATUS

(71) Applicant: Jeong Hwan KIM, Icheon-si (KR)

(72) Inventor: Jeong Hwan KIM, Icheon-si (KR)

(73) Assignee: SK HYNIX INC., Icheon-si (KR)

(21) Appl. No.: 13/563,267

(22) Filed: Jul. 31, 2012

(30) Foreign Application Priority Data
Nov. 29, 2011 (KR) 10-2011-0126143

(51) Int. Cl. G11C 5/02

(52) U.S. Cl. 365/51

(57) ABSTRACT

Provided is a semiconductor apparatus having memory chips stacked along a direction, each memory chip having bit lines and word lines arranged therein and memory blocks each having memory cells. The semiconductor apparatus includes: bit line sense amplifiers coupled to the bit lines arranged in each of the memory chips and configured to enable the bit lines of an enabled memory chip among the plurality of bit lines; and sub word line drivers coupled to the word lines arranged in each of the memory chips and configured to enable word lines of the enabled memory chip among the plurality of word lines. The bit line sense amplifiers and sub word line drivers are provided in any one of the memory chips.

### CROSS-REFERENCES TO RELATED APPLICATION

The present application claims priority under 35 U.S.C. §119(a) to Korean application number 10-2011-0126143, filed on Nov. 29, 2011, in the Korean Intellectual Property Office, which is incorporated herein by reference in its entirety.

### BACKGROUND

1. Technical Field

The present invention relates generally to a semiconductor apparatus and more particularly to a semiconductor apparatus having a structure in which plurality of memory chips are stacked.

2. Related Art

A memory cell array capable of storing data in a semiconductor apparatus in one memory chip includes memory cells that are arranged in rows and columns. The word lines WL are wired along a row direction of the memory cell array, and the bit lines BL are wired along a column direction of the memory cell array. The memory cells C1, C2, C3 to Cn are arranged at the intersections of the word lines WL and the bit lines BL.

FIG. 1 illustrates the coupling relationship between the bit line sense amplifiers BLSA and the memory cells C1, C2, C3 to Cn in a conventional semiconductor apparatus. FIG. 2 illustrates the coupling relationship between the sub word line drivers SWD and the memory cells C1, C2, C3 to Cn in the conventional semiconductor apparatus.

The conventional semiconductor apparatus as shown in FIGS. 1-2 includes a plurality of memory blocks MB1, MB2, MB3 . . . , and each memory block includes a plurality of memory cells C1, C2, C3 to Cn arranged therein.

The plurality of memory cells C1 to Cn in each memory block MB1, MB2, MB3 . . . are coupled to a plurality of bit line sense amplifiers BLSA, respectively, through the top or bottom thereof as shown in FIG. 1, and the plurality of memory cells C1 to Cn are coupled to the plurality of sub word line drivers SWD, respectively, in the left or right side thereof as shown in FIG. 2. The bit line sense amplifiers BLSA serve to sense and amplify the data outputted through a data line using the memory cell array, in which an even bit line and an odd bit line are sequentially arranged, as the data line and a reference line. The sub word line drivers SWD serve to change the word lines to a high or low state.

However, when the bit line sense amplifiers BLSA and the sub word line drivers SWD are arranged as described above in a semiconductor apparatus having a structure of vertically stacked memory chips to increase the memory capacity, it is difficult to control the bit lines and the word lines, and a floating memory cell may occur as a result. These can lead to serious degradation of the reliability of the semiconductor apparatus.

Furthermore, the number of data lines coupled to the bit line sense amplifiers BLSA will inevitably increase in the semiconductor apparatus having a structure of stacked memory chips. These serve as impediments to improving the integration degree of the semiconductor device.

### SUMMARY

A semiconductor apparatus capable of improving the reliability of a semiconductor apparatus having a plurality of memory chips stacked therein by improving the arrangement structure of bit line sense amplifiers and sub word line drivers is described herein.

In one embodiment of the present invention, there is provided a semiconductor apparatus having a plurality of memory chips stacked in a vertical direction, each memory chip having a plurality of bit lines and a plurality of word lines arranged therein and a plurality of memory blocks each having a plurality of memory cells arranged at intersections between the plurality of bit lines and the plurality of word lines. The semiconductor apparatus includes: a plurality of bit line sense amplifiers coupled to the plurality of bit lines arranged in each of the memory chips and configured to enable bit lines of an enabled memory chip among the plurality of bit lines; and a plurality of sub word line drivers coupled to the plurality of word lines arranged in each of the memory chips and configured to enable word lines of the enabled memory chip among the plurality of word lines, wherein the plurality of bit line sense amplifiers and the plurality of sub word line drivers are provided in any one memory chip of the memory chips.

In another embodiment of the present invention, a semiconductor apparatus having a plurality of semiconductor chips stacked in a vertical direction includes: two or more memory chips including a plurality of bit lines and a plurality of word lines arranged in therein and a plurality of memory blocks arranged therein, each memory block having a plurality of memory cells formed at intersections between the plurality of bit lines and the plurality of word lines; and a control chip including a plurality of bit line sense amplifiers coupled to a plurality of bit lines arranged in each of the two or more memory chips and a plurality of sub word line drivers coupled to a plurality of word lines arranged in each of the two or more memory chips.

### BRIEF DESCRIPTION OF THE DRAWINGS

Features, aspects, and embodiments are described in conjunction with the attached drawings, in which:

FIG. 1 illustrates the coupling relations between bit line sense amplifiers and memory cells in a conventional semiconductor apparatus;

FIG. 2 illustrates an example of coupling relationship between the sub word line drivers and the memory cells in the conventional semiconductor apparatus;

FIG. 3 illustrates the configuration of a semiconductor apparatus according to an embodiment of the present invention;

FIG. 4 illustrates the variation of the configuration of a semiconductor apparatus according to an embodiment of the present invention;

FIG. 5 illustrates the coupling relations between a bit line sense amplifier and a plurality of memory chips in the semiconductor apparatus according to an embodiment of the present invention as shown in FIG. 3;

FIG. 6 illustrates an example of coupling relationship between a sub word line driver and the plurality of memory chips in a semiconductor apparatus according to an embodiment of the present invention as shown in FIG. 3; and

FIG. 7 illustrates the structure of the sub word line driver of the semiconductor apparatus according to an embodiment of the present invention as shown in FIG. 3.

### DETAILED DESCRIPTION

Hereinafter, a semiconductor apparatus according to the present invention will be described below with reference to the accompanying drawings through various embodiments of the present invention.

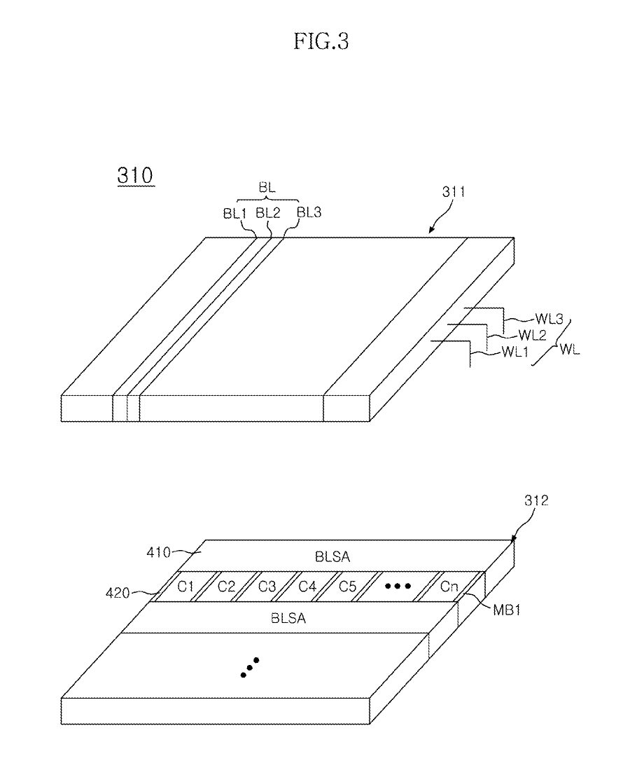

FIG. 3 illustrates the configuration of a semiconductor apparatus according to an embodiment of the present invention.

Referring to FIG. 3, the semiconductor apparatus 310 according to an embodiment includes a plurality of stacked memory chips 311, 312. Although two stackable memory chips are shown in FIG. 3 and described below as an example, it should be readily understood that the present invention is not limited by the number of stacked memory chips. Two or more memory chips may be stacked for high integration according to an embodiment of the present invention.

Each memory chip 311, 312 includes a plurality of bit lines BL1, BL2, BL3 . . . and a plurality of word lines WL1, WL2, WL3 . . . arranged therein and also includes a plurality of memory blocks MB1, MB2 . . . , each memory block including a plurality of memory cells C1 to Cn arranged at the intersections between the bit lines BL1, BL2, BL3 . . . and the word lines WL1, WL2, WL3 . . . .

The semiconductor apparatus 310 according to an embodiment includes a bit line sense amplifier BLSA 410 and a sub word line driver SWD 420, which are provided only in the second memory chip 312 of the memory chips 311, 312. The bit line sense amplifier BLSA 410 is configured to amplify the signal for the data stored in the plurality of memory cells C to Cn, and the sub word line driver SWD 420 is configured to drive the word lines WL1, WL2, WL3 . . . .

The bit line sense amplifier BLSA 410 and the sub word line driver SWD 420, which are provided in the second memory chip 312, control not only the enabling of the bit lines BL1, BL2, BL3 . . . and the word lines WL1, WL2, WL3 . . . arranged in the second memory chip 312, but also the enabling of the bit lines BL1, BL2, BL3 . . . and the word lines WL1, WL2, WL3 . . . arranged in the first memory chip 311.

That is, the second memory chip 312 includes the bit line sense amplifier BLSA 410 and the sub word line driver SWD 420, and the plurality of bit lines BL1, BL2, BL3 . . . and the plurality of word lines WL1, WL2, WL3 . . . in the first memory chip 311 are enabled according to the control of the bit line sense amplifier 410 and the sub word line driver 420 provided in the second memory chip 312.

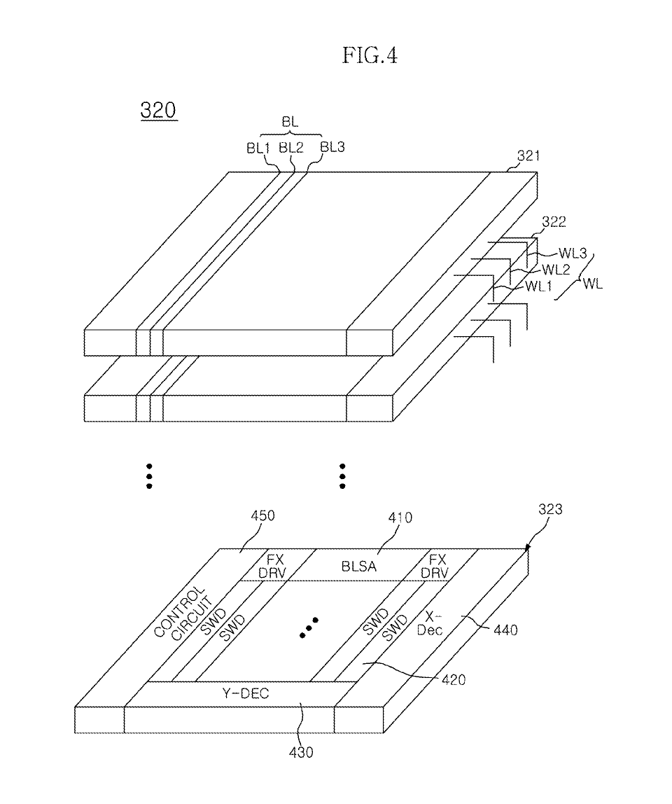

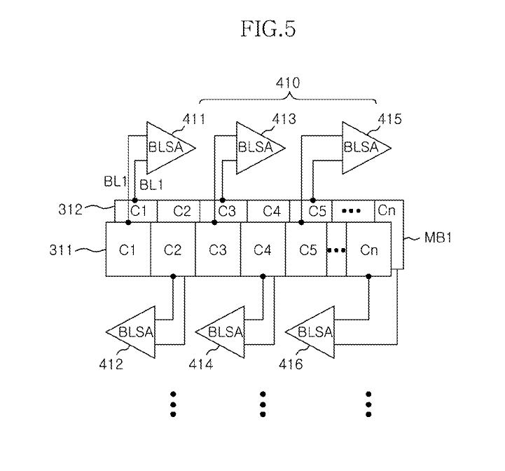

FIG. 4 illustrates a variation of the configuration of a semiconductor apparatus according to an embodiment of the present invention.

Referring to FIG. 4, the semiconductor apparatus 320 according to an embodiment includes stacked memory chips 321, 322 and a control chip 323 having a control circuit provided therein. Although two stacked memory chips are shown in FIG. 4 and described below as an example, it should be readily understood that the present invention is not limited by the number of memory chips. Two, three, or more memory chips may be stacked for high integration according to an embodiment of the present invention.

Each of the memory chips 321, 322 includes a plurality of bit lines BL1, BL2, BL3 . . . and a plurality of word lines WL1, WL2, WL3 . . . arranged therein and also includes a plurality of memory cells C1 to Cn arranged at the intersections between the bit lines BL1, BL2, BL3 . . . and the word lines WL1, WL2, WL3 . . . .

The control chip 323 includes a bit line sense amplifier BLSA 410, a sub word line driver SWD 420, a Y-decoder 430, an X-decoder 440, and a control circuit 450. The bit line sense amplifier BLSA 410 is configured to enable a bit line of an enabled memory chip, among the plurality of bit lines BL1, BL2, BL3 . . . arranged in each of the memory chips 321, 322. The sub word line driver SWD 420 is configured to drive a word line of an enabled memory chip, among the plurality of word lines WL1, WL2, WL3 . . . arranged in each of the memory chips 321, 322. The Y-decoder 430 is configured to receive a command signal from the control circuit 450, decode the received command signal, and output a column address signal of the enabled memory chip. The X-decoder 440 is configured to receive a command signal from the control circuit 450, decode the received command signal, and output a row address signal of the enabled memory chip. The control circuit 450 is configured to receive an address signal and a command signal from outside and control the overall operation of the memory chips 321, 322. That is, the control chip 323 does not itself have a structure in which memory cells for storing data are arranged, but the control chip 323 is configured to control the overall operation of the memory cells in the memory chips 321, 322.

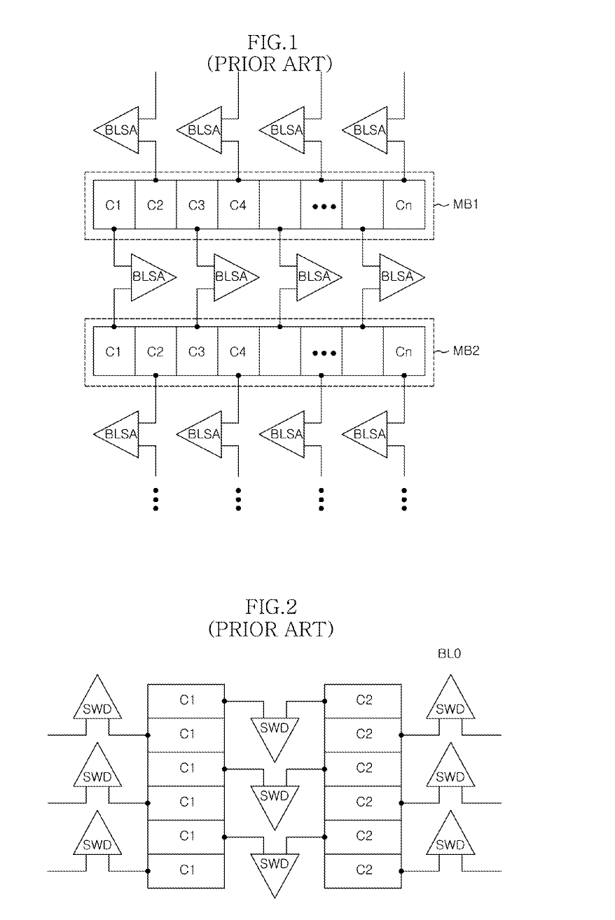

In contrast to a conventional semiconductor apparatus as shown in FIGS. 1-2, it is not necessary to provide the bit line sense amplifiers BLSA 410 and the sub word line drivers SWD 420 in every one of the memory chips 311, 312, 321, 322 in the semiconductor apparatuses 310, 320 shown in FIGS. 3-4. Rather, according to an embodiment of the present invention, the bit line sense amplifiers BLSA 410 and the sub word line drivers SWD 420 may be provided in any one memory chip or a control chip in order to control the plurality of bit lines BL1, BL2, BL3 . . . and the plurality of bit lines WL1, WL2, WL3 . . . which are arranged in each of the memory chips. Therefore, a fail caused by a control error may be reduced, and the number of data lines are also reduced. Accordingly, it improves the high integration of the semiconductor apparatus.

The coupling relationship between the bit line sense amplifier BLSA 410 and the memory chips 311, 312 in the semiconductor apparatus 310 according to an embodiment as shown in FIG. 3 will be described in more detail.

FIG. 5 illustrates the coupling relationship between the bit line sense amplifiers BLSA 410 and the plurality of memory chips 311, 312 in the semiconductor apparatus according to an embodiment as shown in FIG. 3.

Referring to FIG. 5, the bit line sense amplifiers BLSA 410 provided in the second memory chip 312 between the memory chips 311, 312 is coupled to the bit lines BL1, BL2, BL3 . . . arranged in the first memory chip 310 as well as the bit lines BL1, BL2, BL3 . . . arranged in the second memory chip 312.

The coupling relationship between the bit line sense amplifiers BLSA 410 and the respective memory cells will be described as follows. A first bit line sense amplifier 411 is coupled to the bit line BL1 arranged in the first memory cell C1 of the first memory block MB1 of the first memory chip 311 and the bit line BL1 arranged in the first memory cell C1 of the first memory block MB1 of the second memory chip 312.

A second bit line sense amplifier 412 is coupled to the bit line BL2 arranged in the second memory cell C2 of the first memory block MB1 of the first memory chip 311 and the bit line BL2 arranged in the second memory cell C2 of the first memory block MB1 of the second memory chip 312.

The first bit line sense amplifier 411 and the second bit line sense amplifier 412 are arranged on either side of (e.g., above and below seen in FIG. 3) the first memory block MB1. That is, when the first bit line sense amplifier 411 is positioned on one side (e.g., above) the first memory cell C1 of the first memory block MB1, the second bit line sense amplifier 412 is positioned on the other side (e.g., below) the second memory cell C2 of the first memory block MB1. This is because, since the bit line sense amplifiers BLSA 410 are coupled to the plurality of bit lines of the stacked memory chips 311, 312, the space thereof needs to be secured.

The driving characteristic of the bit line sense amplifiers BLSA 410 will be described as follows.

The first bit line sense amplifier BLSA 411 will be taken as an example in describing the driving characteristics of the bit line sense amplifiers BLSA 410. When the first memory cell C1 of the first memory block MB1 of the first memory chip 311 is enabled by the control circuit (not illustrated) between the first bit line BL1 arranged at the first memory cell C1 of the first memory block MB1 of the first memory chip 311 and the first bit line BL1 arranged at the first memory cell C1 of the first memory block MB1 of the second memory chip 312, the first bit line sense amplifier BLSA 411 enables the first bit line BL1 arranged in the first memory cell C1 of the first memory block MB1 of the first memory chip 311. Then, the enabled first bit line BL1 arranged at the first memory cell C1 of the first memory block MB1 of the first memory chip 311 serves as a data line, and the first bit line BL arranged at the first memory cell C1 of the first memory block MB1 of the second memory chip 312 serves as a reference line.

Accordingly, the first bit line sense amplifier 411 serves to amplify the data stored in the first memory cell C1 of the first memory block MB1 of the first memory chip 311.

The semiconductor apparatus 310 according to an embodiment as shown in FIGS. 3 and 5 has been described as an example. However, the coupling relationship between the bit line sense amplifiers BLSA 410 and the memory chips 321, 322 in the semiconductor apparatus 320 according to an embodiment as shown in FIG. 4 may be substantially similar or even identical to those of the semiconductor apparatus 310 according to an embodiment shown in FIGS. 3 and 5, except that, among others, the bit line sense amplifiers BLSA 410 is provided in the control chip 323 in the semiconductor apparatus 320 according to an embodiment as shown in FIG. 4. Therefore, the coupling relationship between the bit line sense amplifiers BLSA 410 and the memory chips 321, 323 in the semiconductor apparatus according to an embodiment as shown in FIG. 4 can be understood based on an embodiment as shown in FIGS. 3 and 5, and the duplicative descriptions thereof are omitted herein.

The sub word line driver SWD 420 of the semiconductor apparatus 310 according to an embodiment as shown in FIG. 3 will be described in more detail.

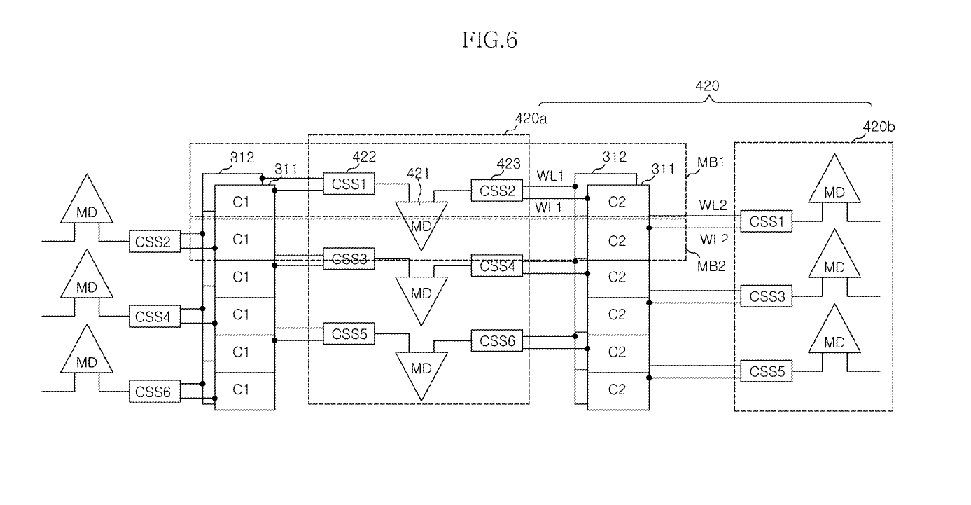

FIG. 6 illustrates the coupling relationship between the sub word line driver SWD 420 and the memory chips 311, 312 in the semiconductor apparatus according to an embodiment as shown in FIG. 3.

Referring to FIG. 6, the sub word line driver 420 provided in the second memory chip 312 of the memory chips 311, 312 is disposed between the first and second memory cells C1, C2 of the first memory block MB1 of the second memory chip 312.

One side of the sub word line driver SWD 420 is coupled to the first word line WL1 arranged at the first memory cell C1 of the first memory block MB1 of the second memory chip 312 and the first word line WL1 arranged at the first memory cell C1 of the first memory block MB1 of the first memory chip 311. The other side of the sub word line driver SWD 420 is coupled to the first word line WL1 arranged at the second memory cell C2 of the first memory block MB1 of the second memory chip 312 and the first word line WL1 arranged at the second memory cell C2 of the first memory block MB1 of the first memory chip 311.

The sub word line driver 420 includes a main driver (MD) 421, a first chip selection switch (CSS1) 422, and a second chip selection switch (CSS2) 423. The first chip selection switch (CSS1) 422 is disposed adjacent to the first memory cell C1 of the first memory block MB1 of the second memory chip 312 around the main driver 421. The second chip selection switch 423 is disposed adjacent to the second memory cell C2 of the first memory block MB1 of the second memory chip 312 around the main driver 421.

The coupling relationship between the memory cells C1, C2, C3, . . . and the chip selection switches CSS1, CSS2, CSS3, . . . will be described as follows. The first chip selection switch CSS1 422 is coupled to the first word line WL1 arranged at the first memory cell C1 of the first memory block MB1 of the second memory chip 312 and the first word line WL1 arranged at the first memory cell C1 of the first memory block MB1 of the first memory chip 311.

The second chip selection switch 423 is coupled to the first word line WL1 arranged at the second memory cell C2 of the first memory block MB1 of the second memory chip 312 and the first word line WL1 arranged at the second memory cell C2 of the first memory block MB1 of the first memory chip 311.

Furthermore, when a first sub word line driver SWD 420a coupled to the first word lines WL1 arranged at the second memory cells C2 of the first memory blocks MB1 of the first and second memory chips 311, 312 is disposed in the left side of the second memory cells C2, a second sub word line driver 420b coupled to the second word lines WL2 arranged at the second memory cells C2 of the second memory blocks MB2 of the first and second memory chips 321, 322 is disposed in the right side of the second memory cells C2. This is because, since the sub word line drivers SWDs are coupled to the plurality of word lines WL of the stacked memory chips 311, 312, the space thereof needs to be secured.

The driving characteristic of the sub word line driver SWD 420 will be described in more detail.

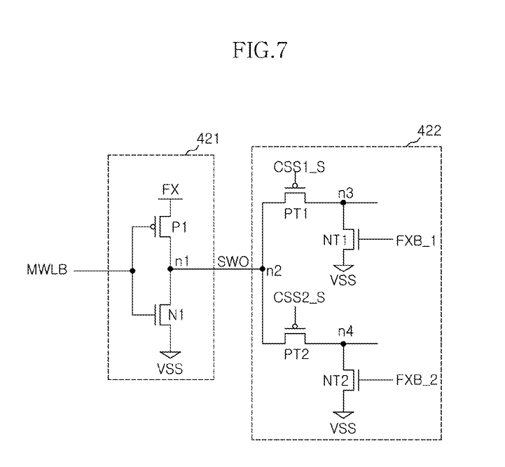

FIG. 7 illustrates the structure of a sub word line driver SWD of the semiconductor apparatus according to an embodiment of the present invention.

Referring to FIG. 7, the sub word line driver SWD 420 of the semiconductor apparatus 310 according to an embodiment includes the main driver MD 421 and the first chip selection switch CSS1 422 as described above. Here, FIG. 7 illustrates only the first chip selection switch CSS1 422, but the circuit configuration thereof is substantially similar or even identical to that of the second chip selection switch CSS2 423.

The main driver MD 421 includes a PMOS transistor P1 and an NMOS transistor N1. The PMOS transistor P1 is configured to pull-up drive a first node n1 in response to an inverted main word line signal MWLB. The NMOS transistor N1 is coupled between the first node n1 and a ground voltage VSS and configured to pull-down drive the first node n1 in response to the inverted main word line signal MWLB. The main driver MD 421 is driven by receiving a sub word line select signal FX inputted from the control circuit as a power supply signal. The main driver MD 421 receiving the sub word line select signal FX and the inverted main word line signal MWLB outputs a sub word line output signal SWO for enabling a selected sub word line SWD.

The first chip selection switch 422 includes a first PMOS transistor PT1, a first NMOS transistor NT1, a second PMOS transistor PT2, and a second NMOS transistor NT2. The first PMOS transistor PT1 is configured to be turned on according to the output signal SWO outputted from the first node n1 of the main driver 421 and whether or not a first chip select signal CSS1_S is inputted from the control circuit. The first NMOS transistor NT1 is coupled between a third node n3 and a ground voltage VSS and configured to pull-down drive the third node n3 in response to an inverted sub word line select signal FXB. The second PMOS transistor PT2 is configured to be turned on according to the output signal SWO outputted from the first node n1 of the main driver 421 and whether or not a second chip select signal CSS2_S is inputted from the control circuit. The second NMOS transistor NT2 is coupled between a fourth node n4 and a ground voltage VSS and configured to pull-down drive the fourth node n4 in response to the inverted sub word line select signal FXB. The first chip selection switch 422 drives a corresponding word line of a corresponding chip which is selected according to the output signal SWO outputted from the main driver 421 and whether or not the first or second select signal CSS1_S or CSS2_S is inputted from the control circuit.

As described above, the semiconductor apparatus according to various embodiments of the present invention includes the bit line sense amplifiers BLSA 410 and the sub word line driver SWD 420 which are positioned only in any one memory chip or control chip of the structure in which the plurality of memory chips are stacked. Accordingly, even in the structure in which the plurality of memory chips are stacked, it is possible to more easily control the bit lines BL and the word lines WL and reduce the number of data lines, all of which allows improving the high degree of integration and the reliability of the semiconductor apparatus.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus having a plurality of stacked memory chips, each memory chip comprising memory blocks, each memory block comprising memory cells configured for data access via bit lines and word lines arranged in each of the memory chips, the semiconductor apparatus comprising:
bit line sense amplifiers provided in one of the memory chips, wherein the bit line sense amplifiers are configured to control enabling of the bit lines in any one of the stacked memory chips; and
sub word line drivers provided in one of the memory chips, wherein the sub word line drivers are configured to control enabling of the word lines in any one of the stacked memory chips.

2. The semiconductor memory according to claim 1, wherein each of the stacked memory chips comprises first and second memory blocks, each of which block comprising first and second groups of memory cells, and wherein the bit line sense amplifiers are comprised of:
a first group of bit line sense amplifiers coupled to a first group of bit lines that are coupled to the first groups of the memory cells of the first memory block in each of the stacked memory chips; and
a second group of bit line sense amplifiers coupled to a second group of bit lines that are coupled to the second groups of the memory cells of the first memory block in each of the stacked memory chips,
wherein any of the memory cells in the first group of memory cells is not arranged contiguous to any of the memory cells in the second group of memory cells in the first memory block in each of the stacked memory chips, and
wherein the first group of bit line sense amplifiers is positioned on a first side of the first memory block, and the second group of bit line sense amplifiers is positioned on the side opposite of the first side with respect to the first memory block.

3. The semiconductor memory according to claim 2, wherein, when the memory cells in the first memory block is arranged in sequence, the first group of memory cells correspond to the odd numbered memory cells and the second group of memory cells correspond to the even numbered memory cells.

4. The semiconductor memory according to claim 2, wherein the first group of bit line sense amplifiers is positioned above the first memory block, and the second group of bit line sense amplifiers is positioned below the first memory block.

5. The semiconductor memory according to claim 2, wherein the plurality of sub word line drivers are comprised of:
a first group of sub word line drivers coupled to a first group of word lines that are coupled to the first groups of the memory cells of the first memory block in each of the stacked memory chips; and
a second group of sub word line drivers coupled to a second group of word lines that are coupled to the first groups of the memory cells of the second memory block in each of the stacked memory chips,
wherein the first group of sub word line drivers is positioned on a second side of the first group of memory cells of the first memory block, and the second group of sub word line drivers is positioned on a second side opposite of the first group of memory cells of the second memory block.

6. The semiconductor memory according to claim 5, wherein the first group of sub word line drivers is positioned on the left side of the first group of memory cells of the first memory block, and the second group of sub word line drivers is positioned on the right side of the first group of memory cells of the second memory block.

7. The semiconductor memory according to claim 5, wherein the first group of sub word line drivers is positioned between the first group of memory cell of one first memory block in each of the stacked memory chips and the second group of memory cells of the first memory block.

8. The semiconductor memory according to claim 5, wherein each of the sub word line drivers comprises:
a main driver configured to receive an inverted main word line signal and a sub word line select signal and output a word line output signal for enabling any one of the word lines; and
a chip selection switch configured to receive the word line output signal outputted from the main driver and a chip select signal and enable the corresponding word line of a selected memory chip.

9. The semiconductor memory according to claim 8, wherein the chip selection switch comprises:
a first group of chip selection switches coupled to the first group of word lines arranged at the first group of memory cells of the first memory block in each of the stacked memory chips; and
a second group of chip selection switches coupled to the first group of word lines arranged at the second group of memory cells of the first memory block in each of the stacked memory chips.

10. A semiconductor apparatus comprising a plurality of stacked semiconductor chips, comprising:
two or more memory chips, each chip comprising bit lines and word lines arranged therein and memory blocks arranged therein, each memory block comprising memory cells formed at intersections of the bit lines and the word lines; and
a control chip comprising bit line sense amplifiers and sub word line driver,
wherein the bit line sense amplifiers are coupled to the bit lines arranged in each of the memory chips and the sub word line drivers are coupled to the word lines arranged in each of the memory chips.

11. The semiconductor memory according to claim 10,
wherein the bit line sense amplifiers are configured to enable bit lines of an enabled memory chip; and
wherein the sub word line drivers are configured to enable word lines of the enabled memory chip.

12. The semiconductor memory according to claim 11, wherein the bit line sense amplifiers are comprised of:
a first bit line sense amplifier coupled to a first bit line arranged at each first memory cell of each first memory block among the plurality of memory blocks arranged in each of the stacked memory chips; and
a second bit line sense amplifier coupled to a second bit line arranged at each second memory cell of each first memory block among the plurality of memory blocks arranged in each of the stacked memory chips,
wherein each first bit line sense amplifier is positioned on a first side of the first memory block, and the second bit line sense amplifier is positioned on a side opposite of the first memory block.

13. The semiconductor memory according to claim 12, wherein the first bit line sense amplifier is positioned above the first memory block, and the second bit line sense amplifier is positioned below the first memory block.

14. The semiconductor memory according to claim 12, wherein the plurality of sub word line drivers comprise:
a first sub word line driver coupled to a first word line arranged at each first memory cell of each first memory block among the plurality of memory blocks arranged in each of the stacked memory chips; and
a second sub word line driver coupled to a second word line arranged at each first memory cell of each second memory block among the plurality of memory blocks arranged in each of the stacked memory chips,
is wherein each first sub word line driver is provided on a second side of each first memory cell of the first memory block, and the second sub word line driver is provided on a side opposite of the second side of each first memory cell of the second memory block.

15. The semiconductor memory according to claim 14, wherein each first sub word line driver is provided above each first memory cell of the first memory block, and the second sub word line driver is provided below each first memory cell of the second memory block.

16. The semiconductor memory according to claim 14, wherein the first sub word line driver is provided between the first memory cell of any one first memory block in the plurality of memory chips and a second memory cell of the first memory block.

17. The semiconductor memory according to claim 14, wherein each of the sub word line drivers comprises:
a main driver configured to receive an inverted main word line signal and a sub word line select signal and output a word line output signal for enabling any one word line of the plurality of word lines; and
a chip select switch configured to receive the word line output signal outputted from the main driver and a chip select signal and enable the corresponding word line of a selected memory chip.

18. The semiconductor memory according to claim 17, wherein the chip selection switch comprises:
a first chip selection switch coupled to the first word line arranged at the first memory cells of the first memory blocks among the plurality of memory blocks arranged in the respective memory chips; and
a second chip selection switch coupled to the first word line arranged at the second memory cells of the first memory blocks among the plurality of memory blocks arranged in the respective memory chips.
